(19) United States
(12) Patent Application Publication
(10) Pub. No.: US 2018/0329242 A1
(43) Pub. Date: Nov. 15, 2018

(54) ACTIVE MATRIX SUBSTRATE AND LIQUID CRYSTAL DISPLAY DEVICE

(71) Applicant: Sharp Kabushiki Kaisha, Sakai City, Osaka (JP)

(72) Inventors: Hideki KITAGAWA, Sakai City (JP); Tohru DAITOH, Sakai City (JP); Hajime IMAI, Sakai City (JP); Toshikatsu ITOH, Sakai City (JP); Hisao OCHI, Sakai City (JP); Tetsuo KIKUCHI, Sakai City (JP); Masahiko SUZUKI, Sakai City (JP); Teruyuki UEDA, Sakai City (JP); Ryosuke GUNJI, Sakai City (JP); Kengo HARA, Sakai City (JP); Setsuji NISHIMIYA, Sakai City (JP)

(21) Appl. No.: 15/776,415

(22) PCT Filed: Feb. 17, 2017
(86) PCT No.: PCT/JP2017/005966

§ 371 Date: May 16, 2018

(30) Foreign Application Priority Data
Feb. 24, 2016 (JP) 2016-033426

(51) Int. Cl. G02F 1/1362; G02F 1/1343; G02F 1/1339; G02F 1/1333; H01L 27/12

(52) U.S. Cl. CPC G02F 1/1362; G02F 1/1343; G02F 2201/123; G02F 1/133345; H01L 27/1214; G02F 1/1339

(57) ABSTRACT

A spacer is fixed while an effect on a surface of an active matrix substrate is prevented. An active matrix substrate (1) includes a thin film transistor (11) which is provided on a substrate (2) and which has a recess made at a surface of the thin film transistor, and a spacer (13) fitted in the recess.

### TECHNICAL FIELD

The present invention relates to an active matrix substrate and a liquid crystal display device including the active matrix substrate. Specifically, the present invention relates to (i) an active matrix substrate including a spacer which is used to retain an interval between the active matrix substrate and a substrate facing the active matrix substrate and (ii) a liquid crystal display device including the active matrix substrate.

### BACKGROUND ART

Recent years have seen vigorous development of an active matrix display device in which a switching element configured by a thin film transistor is provided for each of pixels that are arranged in a matrix. Since the switching element is provided for each pixel, such an active matrix display device brings about an advantage that in a case where a pixel density is increased, the active matrix display can be driven at a lower voltage as compared with a simple matrix type.

Some of active matrix liquid crystal display devices include a spacer for retaining an interval between (i) an active matrix substrate on which a thin film transistor is provided and (ii) a color filter substrate on which a color filter is provided. For example, Patent Literature 1 discloses a liquid crystal display panel including a columnar spacer. The columnar spacer protrudes from an overcoat layer of a color filter substrate toward an active matrix substrate so as to (i) penetrate through a liquid crystal layer and then (ii) comes into contact with an alignment film of the active matrix substrate. This maintains a constant space between the pair of substrates.

### CITATION LIST

### Patent Literature

[Patent Literature 1]

International Publication No. WO 2014/148187 (Publication date: Sep. 25, 2014)

### SUMMARY OF INVENTION

### Technical Problem

However, in a case where a spacer is provided between an active matrix substrate and a color filter substrate as with the liquid crystal display panel disclosed in Patent Literature 1, the following problem may occur. Specifically, when the active matrix substrate and the color filter substrate are to be sealed, the spacer may be pushed toward the two substrates. This may lead to displacement of the spacer. In a case where an alignment film or the like provided on the surface of the active matrix substrate peels off due to the displacement of the spacer, light may leak from the display panel.

The present invention was made in view of the above problem, and an object of the present invention is to provide (i) an active matrix substrate which allows a spacer to be fixed while an effect on a surface of the active matrix substrate is prevented, and (ii) a liquid crystal display device including the active matrix substrate.

### Solution to Problem

In order to attain the above object, an active matrix substrate in accordance with an aspect of the present invention includes: a substrate; a thin film transistor which is provided on the substrate and which has a recess made at a surface of the thin film transistor; and a spacer fitted in the recess.

### Advantageous Effects of Invention

An aspect of the present invention makes it possible to provide an active matrix substrate which allows a spacer to be fixed while an effect on a surface of the active matrix substrate is prevented.

### BRIEF DESCRIPTION OF DRAWINGS

FIG. 1 is an enlarged sectional view illustrating a thin film transistor mounted on an active matrix substrate in accordance with Embodiment 1 of the present invention.

FIG. 2 is an enlarged plan view illustrating a part of the active matrix substrate in accordance with Embodiment 1 of the present invention.

FIG. 3 is a sectional view taken along the line A-A′ in FIG. 2.

FIG. 4 is an enlarged plan view illustrating a part of an active matrix substrate in accordance with Embodiment 2 of the present invention.

FIG. 5 is a sectional view taken along the line B-B′ in FIG. 4.

### DESCRIPTION OF EMBODIMENTS

### Embodiment 1

The following description will discuss Embodiment 1 of the present invention in detail.

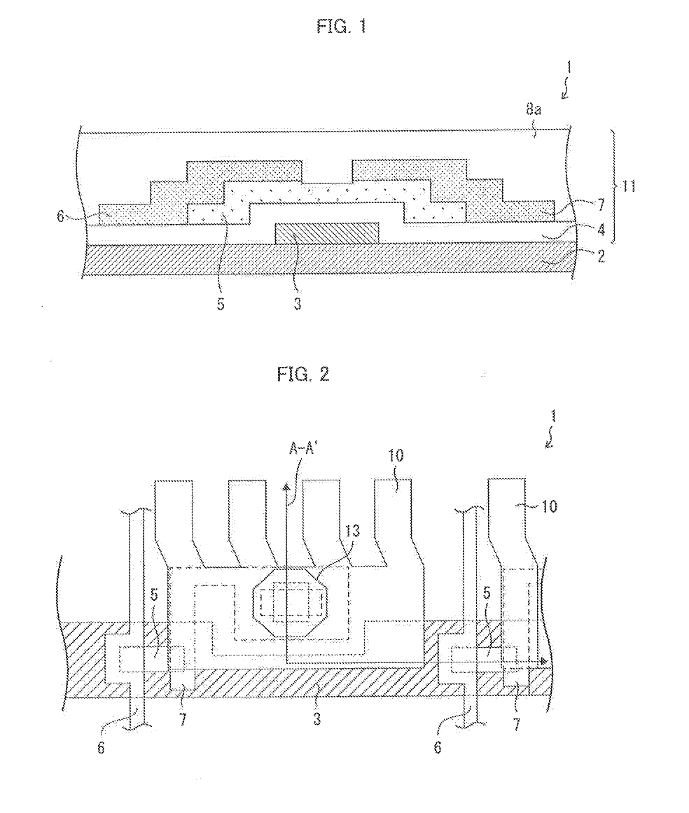

An active matrix substrate in accordance with Embodiment 1 of the present invention is formed by stacking a thin film transistor and a pixel electrode on a substrate. Before discussion of the active matrix substrate in accordance with Embodiment 1, the following description will first discuss, with reference to FIG. 1, a thin film transistor to be mounted on the active matrix substrate. FIG. 1 is an enlarged sectional view illustrating a thin film transistor 11 mounted on an active matrix substrate 1 in accordance with Embodiment 1.

(Thin Film Transistor)

As illustrated in FIG. 1, the thin film transistor 11 includes a gate electrode 3, a gate insulating film 4, an oxide semiconductor film 5, a source electrode 6, a drain electrode 7, and an interlayer insulating film 8a all of which are provided on a substrate 2. The thin film transistor 11 illustrated in FIG. 1 is a channel etch type thin film transistor.

According to the channel etch type thin film transistor 11, no etch stop layer is provided on a channel region, and the source electrode 6 and the drain electrode 7 are arranged such that the lower surfaces of their respective channel side end parts are in contact with an upper surface of the oxide semiconductor film 5 (see FIG. 1). The channel etch type thin film transistor 11 is formed by, for example, (i) forming, on the oxide semiconductor film 5, an electrically conductive film from which the source electrode 6 and the drain electrode 7 are to be formed and (ii) carrying out source-drain separation. In some cases, a surface of the channel region is etched in the step of carrying out source-drain separation.

<Substrate>

The substrate 2 supports the thin film transistor 11. The substrate 2 can be made of any insulating material. Examples of the substrate 2 include (i) a glass substrate and (ii) plastic substrates made of plastic such as polyethylene terephthalate and polyimide.

<Gate Electrode>

The gate electrode 3 is provided on the substrate 2. Hereinafter, in order to define a vertical positional relationship between members that will be discussed in detail, (i) a side of the substrate 2 on which side the gate electrode 3 is provided will be referred to as an upper side and (ii) the other side of the substrate 2 which is opposite to the side on which the gate electrode 3 is provided will be referred to as a lower side.

The gate electrode 3 can be made of a metal material. Examples of the metal material include titanium (Ti), copper (Cu), chromium (Cr), aluminum (Al), gold (Au), and molybdenum (Mo).

<Gate Insulating Film>

The gate insulating film 4 is an insulating film provided on respective upper surfaces of the substrate 2 and of the gate electrode 3 so as to cover the respective surfaces of the substrate 2 and of the gate electrode 3. The gate insulating film 4 can be made of, for example, (i) an organic insulating material such as polyparavinylphenol (PVP) or (ii) an inorganic insulating material such as silicon dioxide (SiO₂).

<Oxide Semiconductor Film>

The oxide semiconductor film 5 is provided on the gate insulating film 4. The oxide semiconductor film 5 is a semiconductor film via which the source electrode 6 is electrically connected to the drain electrode 7. The oxide semiconductor film 5 is made of an oxide semiconductor.

The oxide semiconductor, of which the oxide semiconductor film 5 is made, can be an amorphous oxide semiconductor or a crystalline oxide semiconductor which has a crystalline part. Examples of the crystalline oxide semiconductor include a polycrystalline oxide semiconductor, a microcrystalline oxide semiconductor, and a crystalline oxide semiconductor which has a c-axis oriented so as to be substantially perpendicular to a layer surface.

The oxide semiconductor film 5 can have a structure in which two or more layers are stacked. In a case where the oxide semiconductor film 5 has such a structure, the oxide semiconductor film 5 can include any of the following (i) through (iii): (i) a non-crystalline oxide semiconductor film and a crystalline oxide semiconductor film; (ii) a plurality of crystalline oxide semiconductor films having respective different crystalline structures; and (iii) a plurality of non-crystalline oxide semiconductor films.

In a case where the oxide semiconductor film 5 has a double-layer structure in which an upper layer and a lower layer are included, it is preferable that an oxide semiconductor included in the upper layer has an energy gap greater than that of an oxide semiconductor included in the lower layer. However, in a case where the difference in energy gap between the layers is relatively small, the oxide semiconductor included in the lower layer can have an energy gap greater than that of the oxide semiconductor included in the upper layer.

For example, Japanese Patent Application Publication, Tokukai, No. 2014-007399 discloses, for example, (i) the materials, the structures, and the production methods for the non-crystalline oxide semiconductor and the crystalline oxide semiconductors discussed above and (ii) the configuration of the oxide semiconductor film having a structure in which two or more layers are stacked. The disclosure of Japanese Patent Application Publication, Tokukai, No. 2014-007399 is entirely incorporated herein by reference.

The oxide semiconductor film 5 can include, for example, at least one of the following metal elements: In, Ga, and Zn. In Embodiment 1, the oxide semiconductor film 5 includes, for example, an In—Ga—Zn—O-based semiconductor (e.g., oxide indium gallium zinc). The In—Ga—Zn—O based semiconductor is herein a ternary oxide containing indium (In), gallium (Ga), and zinc (Zn). A ratio (i.e., compositional ratio) between In, Ga, and Zn is not limited to a particular one. Examples of the ratio (In:Ga:Zn) include 2:2:1, 1:1:1, and 1:1:2. Such an oxide semiconductor film 5 can be made of an oxide semiconductor including an In—Ga—Zn—O-based semiconductor.

The In—Ga—Zn—O-based semiconductor can be amorphous or crystalline. A crystalline In—Ga—Zn—O-based semiconductor is preferably a crystalline In—Ga—Zn—O-based semiconductor whose c-axis is oriented so as to be substantially perpendicular to a layer surface.

Note that the crystalline structure of the crystalline In—Ga—Zn—O-based semiconductor is disclosed in, for example, Japanese Patent Application Publication, Tokukai, No. 2014-007399 (discussed above), Japanese Patent Application Publication, Tokukai, No. 2012-134475, and Japanese Patent Application Publication, Tokukai, No. 2014-209727. The disclosures of Japanese Patent Application Publication, Tokukai, No. 2012-134475 and Japanese Patent Application Publication, Tokukai, No. 2014-209727 are entirely incorporated herein by reference.

A thin film transistor including an In—Ga—Zn—O-based semiconductor film has a high mobility (which is more than 20 times greater than that of an a-SiTFT) and a low leakage current (which is less than one hundredth of that of an a-SiTFT). This allows the thin film transistor to be suitably used as a driving thin film transistor or a pixel thin film transistor. The driving thin film transistor is, for example, a thin film transistor included in a driving circuit which is provided (i) in the vicinity of a display region including a plurality of pixels and (ii) on a substrate on which the display region is provided. The pixel thin film transistor is a thin film transistor to be provided in a pixel.

The oxide semiconductor film 5 can include another oxide semiconductor instead of the In—Ga—Zn—O-based semiconductor. Examples of the another oxide semiconductor include an In—Sn—Zn—O-based semiconductor (e.g., In₂O₃—SnO₂—ZnO; InSnZnO) which is a ternary oxide containing indium (In), tin (Sn), and zinc (Zn). Other examples of the another oxide semiconductor include an In—Al—Zn—O-based semiconductor, an In—Al—Sn—Zn—O-based semiconductor, a Zn—O-based semiconductor, an In—Zn—O-based semiconductor, a Zn—Ti—O-based semiconductor, a Cd—Ge—O-based semiconductor, a Cd—Pb—O-based semiconductor, a cadmium oxide (CdO), a Mg—Zn—O-based semiconductor, an In—Ga—Sn—O-based semiconductor, an In—Ga—O-based semiconductor, a Zr—In—Zn—O-based semiconductor, and an Hf—In—Zn—O-based semiconductor.

<Source Electrode and Drain Electrode>

The source electrode 6 and the drain electrode 7 are provided on the gate insulating film 4 so as to be separated from each other. The source electrode 6 and the drain electrode 7 can be each made of a metal material such as titanium (Ti), copper (Cu), chromium (Cr), gold (Au), aluminum (Al), or molybdenum (Mo).

<Interlayer Insulating Film>

The interlayer insulating film 8a is provided on the respective upper surfaces of the gate insulating film 4, the oxide semiconductor film 5, the source electrode 6, and the drain electrode 7, so as to fill a space by which the source electrode 6 and the drain electrode 7 are separated from each other on the gate insulating film 4 and on the oxide semiconductor film 5. The interlayer insulating film 8a can be made of an insulating material identical to or different from that of which the gate insulating film 4 is made.

FIG. 1 illustrates the channel etch type thin film transistor 11. Note, however, that the thin film transistor to be mounted on the active matrix substrate 1 in accordance with Embodiment 1 is not limited to a channel etch type. For example, an etch stopper type thin film transistor can alternatively be mounted on the active matrix substrate 1.

In the etch stopper type thin film transistor, an etch stopper layer is provided on the channel region, and the lower surfaces of respective channel side end parts of a source electrode and of a drain electrode are located, for example, on the etch stopper layer. The etch stopper type thin film transistor is formed by, for example, (i) forming an etch stopper layer which covers a part of an oxide semiconductor film, which part is to serve as a channel region, (ii) forming, on the oxide semiconductor film and on the etch stopper layer, an electrically conductive film from which a source electrode and a drain electrode are to be formed, and (iii) carrying out source-drain separation.

In a case where the configuration of the oxide semiconductor film 5 discussed above is applicable, the thin film transistor to be mounted on the active matrix substrate 1 in accordance with Embodiment 1 can be a double gate type thin film transistor or a top gate type thin film transistor.

(Active Matrix Substrate)

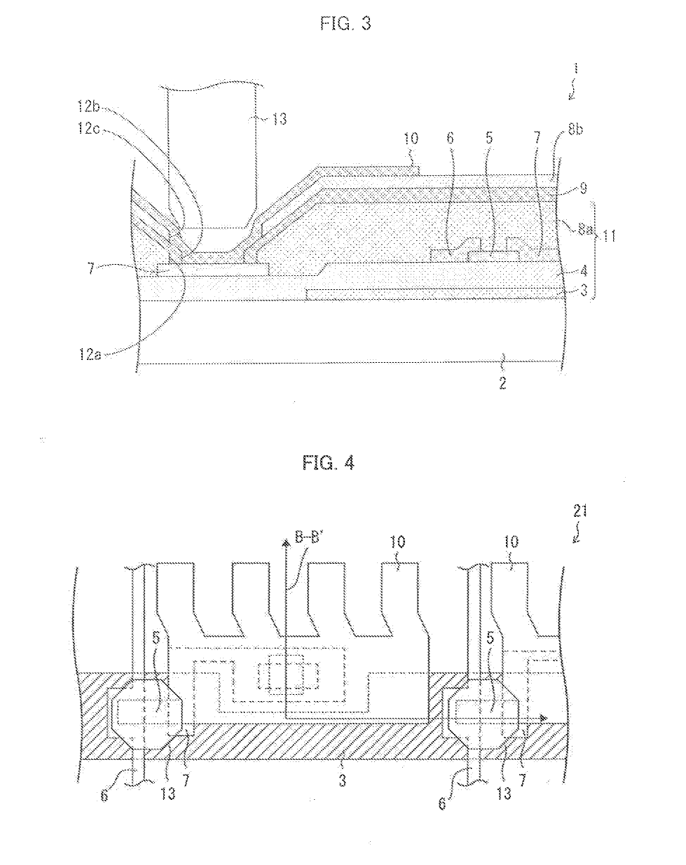

Next, the active matrix substrate 1 in accordance with Embodiment 1 will be discussed below with reference to FIGS. 2 and 3. FIG. 2 is an enlarged plan view illustrating a part of the active matrix substrate 1 in accordance with Embodiment 1. FIG. 3 is a sectional view taken along the line A-A′ in FIG. 2.

As illustrated in FIG. 2, above the drain electrode 7 of the thin film transistor 11, a common electrode 9 and a pixel electrode 10 are overlapping. Between the common electrode 9 and the pixel electrode 10, an interlayer insulating film 8b (second interlayer insulating film) is provided. The interlayer insulating film 8b can be made of an insulating material identical to or different from that of which the gate insulating film 4 is made.

As illustrated in FIG. 3, the interlayer insulating film 8a has a contact hole 12a. The common electrode 9 and the interlayer insulating film 8b have contact holes 12c and 12b (second contact hole), respectively, each of which is made so as to correspond to the contact hole 12a of the interlayer insulating film 8a. The drain electrode 7, the common electrode 9, and the pixel electrode 10 are connected to each other via the contact holes 12a through 12c. An alignment film (not illustrated) is provided so as to cover the upper surface of the pixel electrode 10.

Some of liquid crystal display devices include a spacer for retaining an interval between an active matrix substrate and a color filter substrate (i.e., counter substrate) facing the active matrix substrate, i.e., a spacer for retaining a gap in a liquid crystal layer. Such a spacer is typically placed on a flat part of the upper surface of an interlayer insulating film of the active matrix substrate. However, when the active matrix substrate and the color filter substrate are to be sealed, the spacer may be pushed toward the two substrates. This may lead to displacement of the spacer. In a case where an alignment film provided on the surface of the active matrix substrate peels off due to displacement of the spacer, light may leak from the liquid crystal display device.

Therefore, according to the active matrix substrate 1 in accordance with Embodiment 1, the thin film transistor 11 has a recess which is made at a surface of the thin film transistor 11 and in which a spacer 13 is fitted (see FIG. 3). In FIG. 3, the spacer 13 is fitted, via the pixel electrode 10, in the respective contact holes 12a through 12c of the interlayer insulating films 8a and 8b and the common electrode 9.

This allows the spacer 13 to be fixed to the active matrix substrate 1, and therefore prevents the spacer 13 from being displaced when the active matrix substrate 1 and the color filter substrate are to be sealed. It is therefore possible to fix the spacer 13 while an effect on the surface of the active matrix substrate 1 is prevented. Consequently, since the alignment film provided on the surface of the active matrix substrate 1 is prevented from peeling off due to displacement of the spacer 13, it is possible to prevent leakage of light in the liquid crystal display device.

The spacer 13 can have any shape, provided that the spacer 13 can be fitted in the contact holes 12a through 12c of the interlayer insulating films 8a and 8b and the common electrode 9. Note that the spacer 13 and the contact holes 12a through 12c of the interlayer insulating films 8a and 8b and the common electrode 9 do not necessarily need to have shapes that are complementary to each other, provided that the spacer 13 can be fitted in the contact holes 12a through 12c of the interlayer insulating films 8a and 8b and the common electrode 9.

Note also that, since leakage of light is prevented according to the liquid crystal display device including the active matrix substrate 1 in accordance with Embodiment 1, the liquid crystal display device also has an improved display quality. As such, the scope of the present invention also encompasses the liquid crystal display device including the active matrix substrate 1 in accordance with Embodiment 1.

The above description has discussed an example of a fringe field switching (FFS) mode liquid crystal display device in which the common electrode 9 and the pixel electrode 10 are provided on the active matrix substrate 1. However, the present invention is not necessarily limited to such an example. Alternatively, the active matrix substrate 1 in accordance with the present invention can also be applied to, for example, a twisted nematic (TN) mode liquid crystal display device in which (i) a pixel electrode is provided on an active matrix substrate and (ii) a common electrode is provided on a counter substrate facing the active matrix substrate.

### Embodiment 2

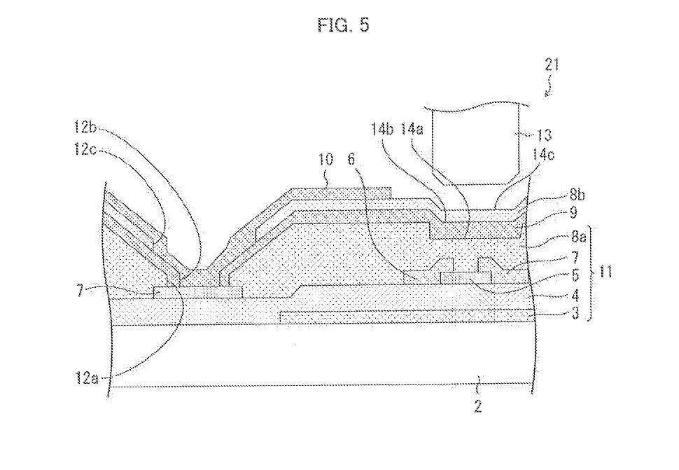

The following description will discuss Embodiment 2 of the present invention with reference to FIGS. 4 and 5. For convenience, members having functions identical to those described in Embodiment 1 are given the same reference numerals, and the descriptions of such members are omitted.

FIG. 4 is an enlarged plan view illustrating a part of an active matrix substrate 21 in accordance with Embodiment 2. FIG. 5 is a sectional view taken along the line B-B′ in FIG. 4.

Conventionally, a spacer for retaining an interval between an active matrix substrate and a color filter substrate is placed on a flat part of the upper surface of an interlayer insulating film of the active matrix substrate. According to Embodiment 1, the spacer is placed above the contact holes of the interlayer insulating film. However, the present invention is not necessarily limited to such a configuration. Alternatively, as with conventional techniques, the spacer can be placed on a flat part of the upper surface of the interlayer insulating film of the active matrix substrate.

According to Embodiment 2, a spacer 13 is not placed above any of contact holes 12a through 12c of interlayer insulating films 8a and 8b and a common electrode 9 of an active matrix substrate 21 (see FIG. 4). Instead, the spacer 13 is placed on flat parts of the respective upper surfaces of the interlayer insulating films 8a and 8b and the common electrode 9 (see FIG. 5). Note that (i) the interlayer insulating film 8a has a recess 14a formed at a position where the spacer 13 is to be provided and (ii) the common electrode 9 and the interlayer insulating film 8b have recesses 14b and 14c (second recess), respectively, each of which is formed so as to correspond to the recess 14a of the interlayer insulating film 8a. The spacer 13 is fitted in the recesses 14a through 14c of the interlayer insulating films 8a and 8b and the common electrode 9. Note that the recesses 14a through 14c of the interlayer insulating films 8a and 8b and the common electrode 9 can be formed by subjecting the interlayer insulating films 8a and 8b and the common electrode 9, respectively, to half-etching.

This allows the spacer 13 to be fixed to the active matrix substrate 21, and therefore prevents the spacer 13 from being displaced when the active matrix substrate 21 and the color filter substrate are to be sealed. It is therefore possible to fix the spacer 13 while an effect on the surface of the active matrix substrate 21 is prevented. Consequently, since the alignment film provided on the surface of the active matrix substrate 21 is prevented from peeling off due to displacement of the spacer 13, it is possible to prevent leakage of light in the liquid crystal display device.

[Recap]

An active matrix substrate 1 in accordance with a first aspect of the present invention includes: a substrate 2; a thin film transistor 11 which is provided on the substrate 2 and which has a recess made at a surface of the thin film transistor; and a spacer 13 fitted in the recess.

According to the above configuration, the spacer 13 is fitted in the recess of the thin film transistor 11 so as to be fixed to the active matrix substrate 1. This prevents the spacer 13 from being displaced when the active matrix substrate 1 and a color filter substrate are to be sealed. It is therefore possible to fix the spacer 13 while and an effect on the surface of the active matrix substrate 1 is prevented.

The active matrix substrate 1 in accordance with a second aspect of the present invention can be configured such that, in the first aspect of the present invention, the thin film transistor 11 includes: a gate electrode 3; a gate insulating film 4 provided on the gate electrode 3; an oxide semiconductor film 5 overlapping the gate electrode 3 with the gate insulating film 4 located between the oxide semiconductor film 5 and the gate electrode 3; a source electrode 6 and a drain electrode 7 each electrically connected to the oxide semiconductor film 5; and an interlayer insulating film 8a which covers the gate insulating film 4, the oxide semiconductor film 5, the source electrode 6, and the drain electrode 7 and which has a contact hole 12a, the spacer 13 being fitted in the contact hole 12a of the interlayer insulating film 8a.

According to the above configuration, the spacer 13 is fitted in the contact hole 12a of the interlayer insulating film 8a. This allows the spacer 13 to be fixed to the active matrix substrate 1.

An active matrix substrate 21 in accordance with a third aspect of the present invention can be configured such that, in the first aspect of the present invention, wherein the thin film transistor 11 includes: a gate electrode 3; a gate insulating film 4 provided on the gate electrode 3; an oxide semiconductor film 5 overlapping the gate electrode 3 with the gate insulating film 4 located between the oxide semiconductor film 5 and the gate electrode 3; a source electrode 6 and a drain electrode 7 each electrically connected to the oxide semiconductor film 5; and an interlayer insulating film 8a which covers the gate insulating film 4, the oxide semiconductor film 5, the source electrode 6, and the drain electrode 7 and which has a contact hole 12a, the interlayer insulating film 8a having a recess 14a which is made at an upper surface of the interlayer insulating film, and the spacer 13 being fitted into the recess 14a of the interlayer insulating film 8a.

According to the above configuration, the spacer 13 is fitted in the recess 14a of the interlayer insulating film 8a. This allows the spacer 13 to be fixed to the active matrix substrate 21.

The active matrix substrate 1 in accordance with a fourth aspect of the present invention can be configured such that, in any one of the first through third aspects of the present invention, the thin film transistor 11 is a channel etch type thin film transistor.

The active matrix substrate 1 in accordance with a fifth aspect of the present invention can be configured such that, in the second or third aspect of the present invention, the oxide semiconductor film 5 is made of a semiconductor which can include an In—Ga—Zn—O semiconductor and which can be a crystalline oxide semiconductor.

The active matrix substrate 1 in accordance with a sixth aspect of the present invention can be configured such that, in the second or third aspect of the present invention, the oxide semiconductor film 5 has a structure in which two or more layers are stacked.

The scope of the present invention also encompasses a liquid crystal display device including: the active matrix substrate 1 or 21 in accordance with any one of the first through sixth aspects of the present invention; and a counter substrate facing the active matrix substrate 1 or 21.

For example, a common electrode 9, a second interlayer insulating film (interlayer insulating film 8b), and a pixel electrode 10 can be provided in this order on the interlayer insulating film 8a of the active matrix substrate 1, the common electrode 9 and the second interlayer insulating film (interlayer insulating film 8b) can have respective second contact holes (contact holes 12b and 12c) each made so as to correspond to the contact hole 12a of the interlayer insulating film 8a, and the spacer 13 can be fitted, via the pixel electrode 10, in the contact hole 12a of the interlayer insulating film 8a and in the respective second contact holes (contact holes 12b and 12c) of the common electrode 9 and of the second interlayer insulating film (interlayer insulating film 8b).

Alternatively, a common electrode 9, a second interlayer insulating film (interlayer insulating film 8b), and a pixel electrode 10 can be provided in this order on the interlayer insulating film 8a of the active matrix substrate 1, the common electrode 9 and the second interlayer insulating film (interlayer insulating film 8b) can have respective second recesses (recess 14b, 14c) which are made at respective upper surfaces of the common electrode 9 and the second interlayer insulating film (interlayer insulating film 8b), so as to correspond to the recess 14a of the interlayer insulating film 8a, and the spacer 13 can be fitted in the recess 14a of the interlayer insulating film 8a and in the second recesses (recess 14b, 14c).

The present invention is not limited to the foregoing embodiments, but can be altered by a skilled person in the art within the scope of the claims. An embodiment derived from a proper combination of technical means disclosed different embodiments is also encompassed in the technical scope of the present invention. Further, it is possible to form a new technical feature by combining the technical means disclosed in the respective embodiments.

### REFERENCE SIGNS LIST

1, 21: Active matrix substrate
2: Substrate
3: Gate electrode
4: Gate insulating film
5: Oxide semiconductor film
6: Source electrode
7: Drain electrode
8a, 8b: Interlayer insulating film
9: Common electrode
10: Pixel electrode
11: Thin film transistor
12a through 12c: Contact hole
13: Spacer
14a through 14c: Recess

1-10. (canceled)

11. An active matrix substrate, comprising:
a substrate;
a thin film transistor which is provided on the substrate and which has a recess made at a surface of the thin film transistor; and
a spacer fitted in the recess.

12. The active matrix substrate as set forth in claim 11, wherein the thin film transistor includes:
a gate electrode;
a gate insulating film provided on the gate electrode;
an oxide semiconductor film overlapping the gate electrode with the gate insulating film located between the oxide semiconductor film and the gate electrode;
a source electrode and a drain electrode each electrically connected to the oxide semiconductor film; and
an interlayer insulating film which covers the gate insulating film, the oxide semiconductor film, the source electrode, and the drain electrode and which has a contact hole.

13. The active matrix substrate as set forth in claim 12, wherein
the spacer being fitted in the contact hole of the interlayer insulating film.

14. The active matrix substrate as set forth in claim 12, wherein
the interlayer insulating film having a recess which is made at an upper surface of the interlayer insulating film, and
the spacer being fitted into the recess of the interlayer insulating film.

15. The active matrix substrate as set forth in claim 11, wherein the thin film transistor is a channel etch type thin film transistor.

16. The active matrix substrate as set forth in claim 12, wherein the oxide semiconductor film is made of a semiconductor including an In—Ga—Zn—O-based semiconductor.

17. The active matrix substrate as set forth in claim 12, wherein the oxide semiconductor film is made of a crystalline oxide semiconductor.

18. The active matrix substrate as set forth in claim 12, wherein the oxide semiconductor film has a structure in which two or more layers are stacked.

19. A liquid crystal display device, comprising:
an active matrix substrate recited in claim 11; and
a counter substrate facing the active matrix substrate.

20. A liquid crystal display device, comprising:
an active matrix substrate recited in claim 12; and
a counter substrate facing the active matrix substrate.

21. The liquid crystal display device as set forth in claim 20, wherein:
a common electrode, a second interlayer insulating film, and a pixel electrode are provided in this order on the interlayer insulating film of the active matrix substrate;
the common electrode and the second interlayer insulating film have respective second contact holes each made so as to correspond to the contact hole of the interlayer insulating film; and
the spacer is fitted, via the pixel electrode, in the contact hole of the interlayer insulating film and in the respective second contact holes of the common electrode and of the second interlayer insulating film.

22. The liquid crystal display device as set forth in claim 20, wherein:
a common electrode, a second interlayer insulating film, and a pixel electrode are provided in this order on the interlayer insulating film of the active matrix substrate;
the common electrode and the second interlayer insulating film have respective second recesses which are made at respective upper surfaces of the common electrode and of the second interlayer insulating film, so as to correspond to the recess of the interlayer insulating film; and
the spacer is fitted in the recess of the interlayer insulating film and in the second recesses.
